(19) United States
(12) Patent Application Publication
(10) Pub. No.: US 2026/0129779 A1
(43) Pub. Date: May 7, 2026

(54) POWER CONVERSION DEVICE

(71) Applicant: LG INNOTEK CO., LTD., Seoul (KR)

(72) Inventor: Mi Sun LEE, Seoul (KR)

(73) Assignee: LG INNOTEK CO., LTD., Seoul (KR)

(21) Appl. No.: 18/703,896

(22) PCT Filed: Dec. 8, 2022
(86) PCT No.: PCT/KR2022/019955

§ 371 Date: Apr. 23, 2024

(30) Foreign Application Priority Data
Dec. 9, 2021 (KR) 10-2021-0176156

(51) Int. Cl. H02M 7/00; H05K 7/14; H05K 7/20

(52) U.S. Cl. CPC H05K 7/14322; H05K 7/20463; H02M 7/003; H05K 7/1432

(57) ABSTRACT

A power conversion device according to one embodiment of the present invention comprises: a case including a base and a side plate extending in the vertical direction from the base; a substrate disposed inside the case and facing the base; and one or more first holes which are formed in the side plate of the case and through which cables connected to the substrate passes, wherein the first holes are formed at positions corresponding to positions where the cables are connected to the substrate.

### TECHNICAL FIELD

The teachings in accordance with exemplary and non-limiting embodiments of this invention relate generally to a power conversion device, and more particularly, to a power conversion device applied with a molding structure, a power conversion device case and a power conversion device manufacturing method.

### BACKGROUND ART

Photovoltaic power generation is an eco-friendly energy generation method that has been widely used to replace conventional chemical and nuclear power generation. The photovoltaic power generation may include a stand-alone type where batteries are connected to a converter, and grid-connected system. In general, stand-alone power generation consists of solar cells, storage batteries, and power conversion devices, while grid-connected systems are connected to commercial power sources so that power can be exchanged with the load grid.

Solar modules have different maximum points depending on sunlight, temperature, etc. To operate solar cells at their maximum power point, module-level power electronics (MLPE) with maximum power point tracking (MPPT) control on a module-by-module basis can be used. Because MLPEs include many power conversion elements for maximum power point tracking, they can generate a lot of heat during the power conversion process. Since the temperature rise caused by heat affects the power conversion, a structure with effective heat dissipation is required.

### DETAILED DESCRIPTION OF INVENTION

### Technical Subject

The technical problem that the present invention seeks to solve is to provide a power conversion device applied with a molding structure, a power conversion device case and a power conversion device manufacturing method.

### Technical Solution

In order to solve the technical subject, a power conversion device according to an exemplary embodiment of the present invention may comprise: a case including a base and a side plate extending in the vertical direction from the base;
a substrate disposed inside the case and facing the base; and
one or more first holes which are formed in the side plate of the case and through which cables connected to the substrate passes, wherein
the first holes are formed at positions corresponding to positions where the cables are connected to the substrate.

Preferably, but not necessarily, the first hole may be formed at a location corresponding to a length from the base to a second surface of the substrate which is an opposite side of the first surface of the base.

Preferably, but not necessarily, the interior of the case may be filled with a molding fluid and molded.

Preferably, but not necessarily, the power conversion device may include a connector connecting the cable to the substrate by being disposed on a second surface of the substrate opposite a first surface of the base.

Preferably, but not necessarily, the power conversion device may include a fixture projecting from a side of the base opposite the substrate corresponding to a position of the connector, wherein the substrate may include a second hole corresponding to the fixture, and the connector may be able to engage the fixture, the substrate, and the cable.

Preferably, but not necessarily, the power conversion device may include a cover that faces the base and that covers the case.

Preferably, but not necessarily, the power conversion device may include a fastener for fastening the cable to the first hole.

Preferably, but not necessarily, the fastener may include: a first plate; a stepped portion projecting from one surface of the first plate; and a third hole through the first plate and the end portion, with the cable located therein, the third hole having a length from a center of the third hole to an outermost edge of the stepped portion corresponding to a radius of the first hole.

Preferably, but not necessarily, the cross-sectional shape of the stepped portion may be a ring shape in which a hole is formed, or a shape comprising a ring shape and a plurality of protrusions projecting from the ring shape.

Preferably, but not necessarily, the fastener may include: a first fastener comprising a semicircular first rib in contact with the cable in a first direction, on which the cable is located; and a second fastener comprising a semicircular second rib in contact with the cable in a second direction opposite to the first direction, on which the cable is located.

Preferably, but not necessarily, the first rib and the second rib may form a third hole in which the cable is disposed.

Preferably, but not necessarily, the cable may include one or more input cables to receive power and one or more output cables to output power.

Preferably, but not necessarily, the substrate may include power conversion elements that receive and convert multi-level power.

In order to solve the technical subject, a power conversion device case according to an exemplary embodiment of the present invention may comprise:
a base;
a side plate extending perpendicularly from the base; and
at least one first hole formed in the side plates of the case, the first hole being formed at a location corresponding to a location where a cable connecting to a substrate disposed inside the case is passed through, the cable connecting to the substrate.

In order to solve the technical subject, a power conversion device manufacturing method according to an exemplary embodiment of the present invention may comprise:
disposing a substrate inside the case opposite a base of the case; passing a cable through a first hole formed in a side plate extending from the base of the case, and joining the base, the substrate, and the cable with a connector;
closing a space between the first hole and the cable with a fastener securing the cable to the first hole; and
molding the interior of the case by filling the same with a molding liquid.

Preferably, but not necessarily, the manufacturing method may include the steps of engaging the first hole and the cable from the exterior side of the case, and removing the fastener after the molding step.

Preferably, but not necessarily, the manufacturing method may include the step of covering the case with a cover after the step of molding.

### Advantageous Effect

According to embodiments of the present invention, in applying the molded structure, reliability can be ensured by preventing bending of the cable, and fire can be prevented. Furthermore, cost can be reduced by eliminating the need for connectors to compensate for height, and size can be reduced by eliminating the need for a cable bending space.

### BRIEF DESCRIPTION OF DRAWINGS

FIGS. 1 and 2 illustrate a power conversion device according to a comparative embodiment of the present invention.

FIG. 3 is a perspective view of a power conversion device according to an exemplary embodiment of the present invention.

FIGS. 4 to 12 are drawings to illustrate a power conversion device according to an embodiment of the present invention.

FIG. 13 is a flow chart of a power conversion device manufacturing method according to an exemplary embodiment of the present invention.

FIGS. 14 and 15 are flow charts of a power conversion device manufacturing method according to another exemplary embodiment of the present invention.

### BEST MODEL

Hereinafter, exemplary embodiments of the present invention will be described in detail with reference to the accompanying drawings.

However, the present invention is not limited to the given exemplary embodiments described, but may be implemented in a variety of different forms, and one or more of components among the exemplary embodiments may be optionally combined or substituted between embodiments within the scope of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invention.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,” “coupled,” or “attached” to another component that is between the component and the other component.

Furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component.

Variations (modifications) according to the present disclosure may include some configurations of each embodiment together with some configurations of other embodiments. That is, a variation may include an embodiment of one of the various embodiments but omit some configurations and include some configurations of a corresponding other embodiment. Alternatively, it may be the other way round. The features, structures, effects, etc. described in the embodiments are included in at least one embodiment and are not necessarily limited to one embodiment. Furthermore, the features, structures, effects, etc. exemplified in each embodiment may be combined or modified in other embodiments by one having ordinary skill in the field to which the embodiments belong. Accordingly, such combinations and modifications should be construed as being within the scope of the embodiments.

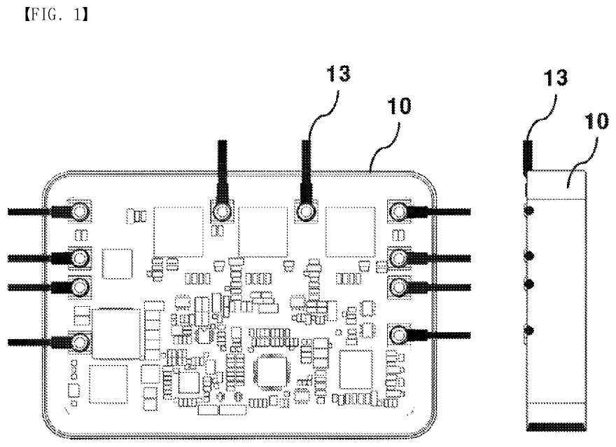

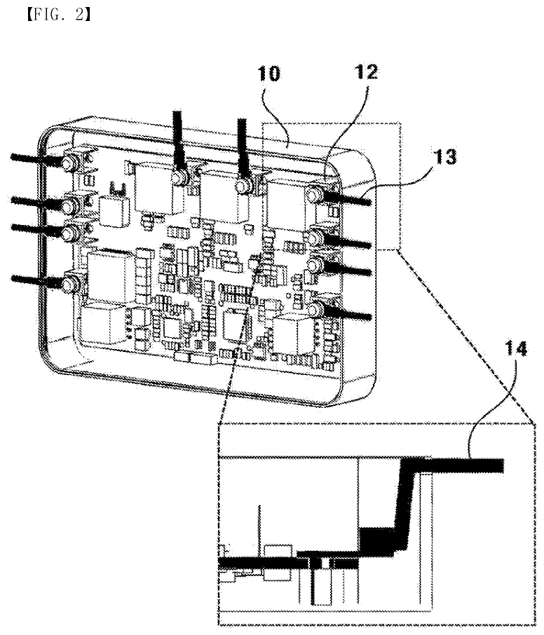

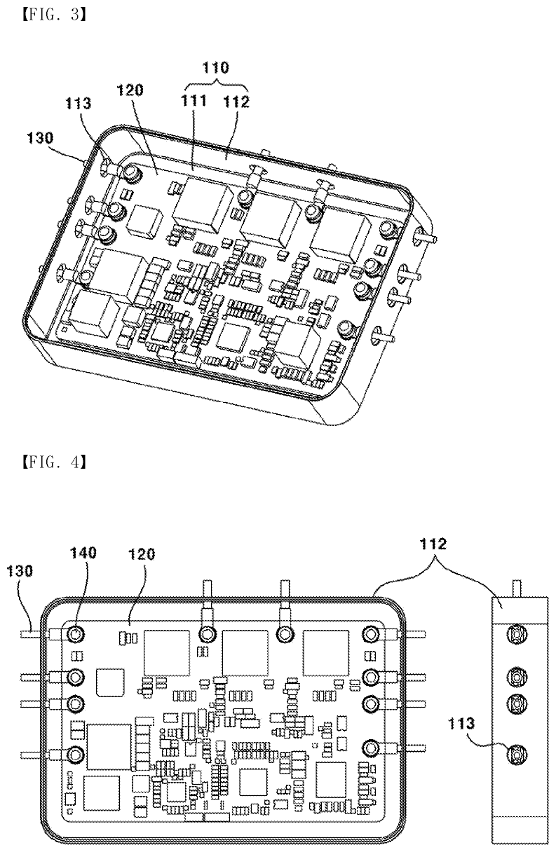

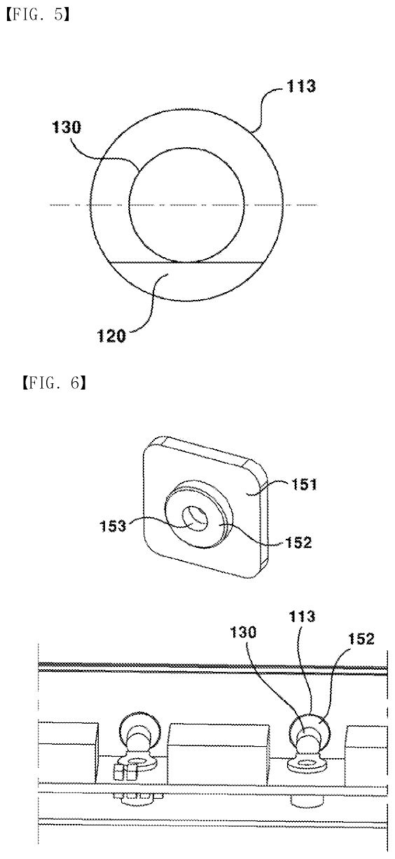

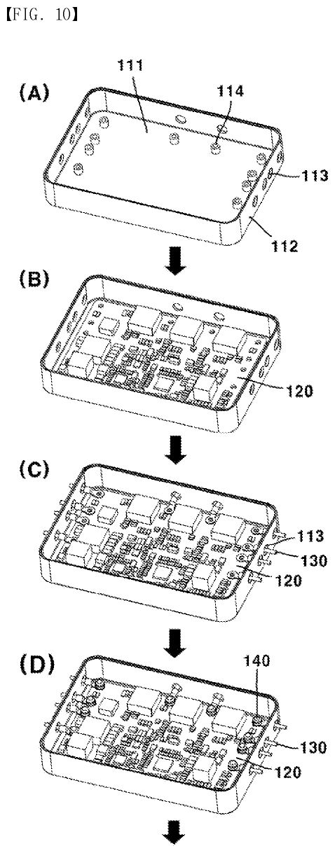

FIGS. 1 and 2 illustrate a power conversion device according to a comparative embodiment of the present invention, FIG. 3 is a perspective view of a power conversion device according to an exemplary embodiment of the present invention, and FIGS. 4 to 12 are drawings to illustrate a power conversion device according to an embodiment of the present invention.

Since power conversion devices generate a lot of heat during the process of converting power, heat dissipation is necessary. Here, the power conversion device according to an embodiment of the present invention may be a module-level power electronics (MLPE). An MLPE is a power conversion device applied to a solar power generation system, where the power generated by a single solar cell is insufficient for use in a load or power grid, so a plurality of solar cells, rather than a single solar cell, can be connected in series to form a solar cell string to generate power of a suitable size for use. A solar cell string may be the basic unit of power generation. A plurality of cell strings can be formed into a panel to form a solar panel. Solar cells have different voltage-current characteristics, and their maximum power point (MPP) fluctuates depending on sunlight, temperature, etc. (Power Generated=Voltage×Current) The power inversion device controls the solar cell to operate at the maximum power point (MPP), which is the operating point at which the solar cell generates the maximum power under each condition. This is called maximum power point tracking (MPPT), and it can be used to increase the efficiency of solar power generation. Depending on the nature of the relationship between current and voltage in solar power generation and the relationship between voltage and power, the maximum power may not be the maximum voltage, but rather the power at about 80% of the maximum voltage. This peak power point is constantly changing depending on the magnitude of the voltage and current generated by the solar panel, so it is necessary to keep looking for the point where the peak power point can be generated. In other words, to pursue maximum power rather than maximum voltage, the magnitude of the voltage and current can be varied to achieve maximum power, i.e., the voltage can be decreased and the current increased in the direction of increasing power, or the voltage can be increased and the current decreased. The power conversion device may include a plurality of converters, and the plurality of converters may comprise a multilevel. To form the multilevel, the plurality of converters may be connected in a cascode. Here, cascode refers to a form in which the outputs are connected in multiple stages, and the outputs of the converters are stacked according to the cascode connection to form a multilevel.

Multilevel refers to a structure in which the output signals of each converter are combined into a single signal and outputted. In this case, the (−) terminal of the output of the upper level converter is sequentially connected to the (+) terminal of the output of the neighboring lower level converter, and the outputs of the highest level converter and the output of the lowest level converter are combined and outputted as one signal. When operating the MLPE, a lot of heat is generated, so for heat dissipation, a heat sink can be used or molding can be applied by pouring molding liquid inside the case. In the case of molding, in order to prevent the molding liquid from leaking out through the hole through which the connecting cable passes, a cable (13) can be connected through a hole formed at the uppermost end of a side plate (10) of the case, as shown in FIG. 1.

In this case, cables (13), such as power input and output lines, are connected to the substrate, but since the substrate and the location where the cables pass through the side plate (10) are at different heights, a connection terminal (12) that compensates for this must be applied, as shown in FIG. 2. The unit price of the product will increase if the connection terminal 12 is applied. If the connection terminal (12) is not applied, there may be a problem of bending of cable (13) as shown in FIG. 2 and below, and there may be a problem of not securing reliability of power conversion device that requires long life due to short circuit, ignition, etc.

For effective heat dissipation using molding, a power conversion device according to one embodiment of the present invention may comprise a case (110) including a base (111) and a side plate (112), a substrate (120), and a first hole (113) formed in the side plate (112), and may include a connector (140), a fixture (114), a fastener (150), a cover (170), and the like.

A power conversion device according to an embodiment of the present invention may be formed as shown in FIGS. 3 and 4.

The case (110) may include a base (111) and a side plate (112) extending vertically from the base (111).

The base (111) is planar in shape, and the side plates (112) extend perpendicularly from the edges of the base (111), forming an interior space to receive the substrate (120). Here, the side plate (112) may be formed of four side plates that are integrally molded.

The substrate (120) may be disposed inside the case (110) opposite the base (111). Power conversion elements that convert power may be disposed on the substrate (120).

Here, the power conversion elements may be elements that receive and convert multi-level power. Power conversion elements may include converters, including inductors and switching elements, for example, buck converters, boost converters, buck-boost converters, and the like, and may include bypass diodes, and the like. They may also include passive elements such as capacitors and resistors or active elements such as control ICs. In addition, it can include various elements necessary to convert power. In this case, heat may be generated when converting power in the power conversion element. In particular, diodes and inductors can generate a lot of heat. In order to dissipate the heat generated by the power conversion element to the outside, heat dissipation is required, and for heat dissipation, molding can be performed by filling the inside of the case (110) with a molding liquid. Here, the molding fluid is a material with high thermal conductivity, and by pouring the liquid molding fluid into the interior of the case (110) and allowing it to harden, heat can be effectively dissipated through the molding fluid to the outside. The molding fluid may include various molding fluids, such as epoxy.

In performing the power conversion, a cable (130) may be connected to the outside world to receive power input, convert the input power, and output the power. The cable (130) may include one or more input cables to receive power and one or more output cables to output power. In the case of a multi-level MLPE, it may include a plurality of input cables. It may also include other types of cables, such as communication cables that receive control signals from the outside world or send and receive data to and from the outside world.

At this time, the case (110) may include at least one first hole (113) formed in the side plate (112) of the case (110) through which the cable (130) passes to allow the cable (130) to connect with the substrate (120) being disposed inside the case (110). Here, the first holes (113) may be formed at locations corresponding to locations where the cable (130) connects to the substrate (120). The first holes (113) may be formed in a position such that the cable (130) can be withdrawn directly from the location where it connects with the substrate (120) without bending.

Since the first hole (113) is formed at a location corresponding to the location where the cable (130) and the substrate (120) are connected, the cable (130) can be pulled out through the first hole (113) directly from the location where the cable (130) is connected to the substrate (120). Since it is unnecessary to have a separate connection terminal (12) to compensate for the t height of the cable (130) or to bend the cable (130), reliability can be secured by preventing the cable from bending, and risks such as fire that may occur due to the bending of the cable can be prevented. Furthermore, the cost can be reduced by eliminating the connection terminal (12) for height compensation, and the space for bending the cable (130) can be reduced, thereby reducing the overall size.

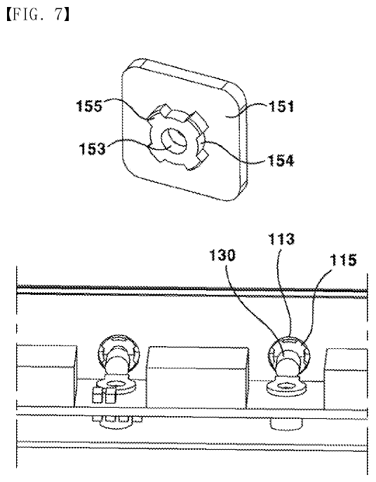

To eliminate or minimize kinks in the cable (130), the first hole (113) can be formed in a position where the center of the cable (130) and the center of the first hole (113) are concentric. As shown in FIG. 5, the cable (130) and the first hole (113) may be formed concentrically. To this end, the first hole (113) may be formed at a location corresponding to a length from the base (111) to a second surface of the substrate (120) opposite the first surface of the base (111). A cable (130) may be formed at a location corresponding to a length from the base (111) to the second surface, which is the opposite side of the first surface of the substrate (120) that faces away from the base (111), when the substrate (120) is disposed inside the case (110). Depending on the connection structure of the substrate (120) and the cable (130), the substrate (120) and the first hole (113) may overlap each other at least partially, or the substrate (120) and the first hole (113) may be spaced apart from each other without overlapping.

The cable (130) and the substrate (120) may be connected via a connector (140). The connector (140) may be disposed on a second surface of the substrate (120) to connect the cable (130) and the substrate (120). The connector (140) may include various structures to connect the cable (130) and the substrate (120). For example, a second hole may be formed in the second surface of the substrate (120), the end of the cable (130) may be formed in a closed loop shape or a partially open ring shape, and the connector (140) may have a screw structure that presses the cable (130) and the second hole in the substrate (120) together. It may also include a structure for joining the cable (130) and the substrate (120) via soldering or bolting.

The base (111) may include a fixture (114) projecting from a first surface of the base (111) corresponding to a location of the connector (140), the substrate (120) may include a second hole corresponding to the fixture (114), and the connector (140) may join the fixture (114), the substrate (120), and the cable (130) together. Here, the fixture (114) may be formed to protrude from the base (111) at a location where the connector (140), the substrate (120), and the cable (130) are connected. The fixture (114) may be formed on an imaginary line extending from a location on the side plate where the first hole (113) is formed. The fixture (114) may be shaped to insert into the second hole of the substrate (120), such that the fixture (114) may guide assembly of the substrate (120) by positioning the second hole of the substrate (120) in the fixture (114) when the substrate (120) is placed inside the case (110). When the substrate (120) is placed inside the case (110), the fixture (114), the second hole in the substrate (120), and the cable (130) can be positioned in the same location, and the fixture (114), the substrate (120), and the cable (130) can be joined together and secured via the connector (140).

As shown in FIG. 5, the cable (130) and the first hole (113) are formed concentrically, but to facilitate passing the cable (130) through the first hole (113), the first hole (113) may be formed wider than the cross-sectional area of the cable (130) or the width of the connection terminal of the cable (130). The first hole (113) may be formed wider than the width of the connection terminal of the cable (130) that connects to the substrate (120). For example, if it is formed as a closed loop, such as a ring, it can be formed wider than the width of the closed loop terminal to allow the terminal of the cable to pass through. It can be formed at least 4 mm wider than the width of the cable terminal.

Because the first hole (113) is formed wider than the cross-sectional area of the cable (130), when filling the inside of the case (110) with molding fluid, the molding fluid may leak into the space between the cable (130) and the first hole (113). To prevent molding fluid from leaking out, the space between the cable (130) and the first hole (113) should be closed. To do so, the cable (130) may include a fastener (150) that fastens the cable (130) to the first hole (113). The fastener (150) may be positioned inside the cable (130), but can be threaded into the first hole (113) to fasten the cable (130) to the first hole (113), thereby closing off the space between the cable (130) and the first hole (113). By filling the molding fluid with the cable (130) while the cable (130) is secured to the first hole (113) using the fastener (150), the molding fluid can be prevented from leaking into the space between the cable (130) and the first hole (113).

The fastener (150) may include a first plate (151), a stepped portion (152) projecting from one surface of the first plate (151), and a third hole (153) through which the cable (130) is located and through which the first plate (151) and the stepped portion (152) pass. Here, the stepped portion (152) may have a length from the center of the third hole (153) to the outermost edge of the stepped portion (152) corresponding to the radius of the first hole (113). The fastener (150) may include a stepped portion (152) projecting from the first plate (151) to fit into the first hole (113) and a third hole (153) into which the cable (130) is threaded.

While engaged with the cable (130) through the third hole (153) corresponding to the cross-section of the cable (130), the stepped portion (152) corresponding to the first hole (113) can be inserted into the third hole (153) to engage the cable (130) and the first hole (113). This allows the first plate (151) to be closely fitted to the side plate (112), which prevents molding fluid from leaking out. It also serves to hold the cable (130) during molding, preventing the cable (130) from bending during the molding process.

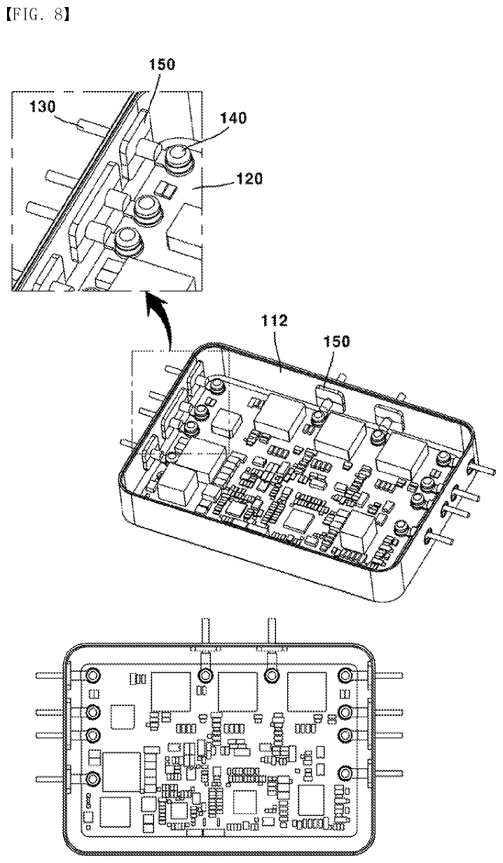

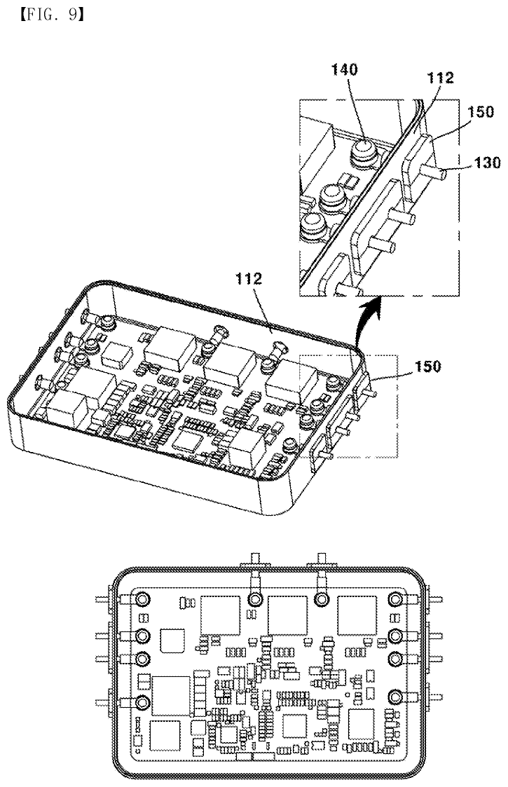

The cross-sectional shape of the stepped portion (152) may be a ring shape in which a hole is formed, as shown in FIG. 6, or a shape including a ring shape (154) and a plurality of protrusions (155) projecting from the ring shape (154), as shown in FIG. 7. In the case of including a plurality of protrusions (155), the shape of the first hole (113) may be formed to correspond to the shape of the stepped portion in FIG. 7. The connection terminal of the cable (130) may pass through the space in the first hole (113) corresponding to the protrusions (155), and not through any other space, which may prevent the cable (130) from slipping back out, and may prevent the fastener (150) from rotating after engagement with the first hole (113), thereby firmly securing the cable (130) and the first hole (113).

Here, the diameter of the ring-shape (152) of FIG. 6 corresponds to the diameter of the first hole (113), and the diameter of the ring-shape (154) of FIG. 7 is smaller than the diameter of the ring-shape (152) of FIG. 6 or the first hole (113), but the length from the center of the third hole (153) to the distal end of the protrusion (155), which is the outermost portion of the stepped portion (152), corresponds to the radius of the first hole (113) and can be fitted and secured in the first hole (113).

In this case, the fastener (150) may be formed of a resilient material, subject to tolerances. For example, it may be formed of a resilient material, such as rubber, and may be pressurized to seat the cable (130) and fit into the first hole (113) for a tight fit. In this case, the diameter of the third hole (153) may be a predetermined length smaller than the diameter of the cable (130), and the longest length of the cross-sectional area of the stepped portion (152) may be a predetermined length longer than the first hole (113). The offset length may be preset by a user.

The fastener (150) may be fastened inside the case (110), as shown in FIG. 6, or outside the case (110), as shown in FIG. 7. If the fastener (150) is fastened inside the case (110), when the molding fluid cures, the fastener (150) will cure together. On the other hand, if the fastener (150) is secured outside of the case (110), the fastener (150) can be removed after the molding fluid has cured. If the fastener (150) is fastened outside of the case (110), it can be used as a jig and remain in service. The fastener (150) may include a first fastener (156) and a second fastener (157) to allow the cable (130) to pass through the first hole (113) and be engaged while connected to the substrate (120).

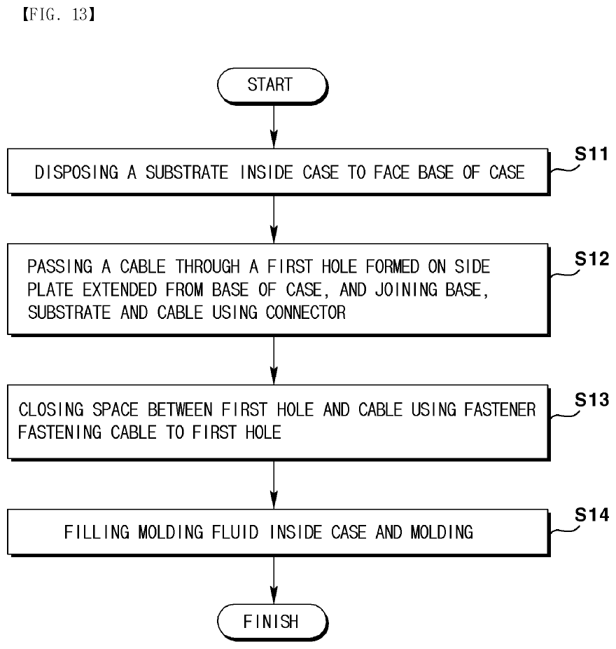

The fastener may include a first fastener (156) that contacts the cable (130) in a first direction and includes a semi-circularly shaped first rib on which the cable is positioned, and a second fastener (157) that contacts the cable (130) in a second direction that is opposite to the first direction and includes a semi-circularly shaped second rib on which the cable (130) is positioned. As shown in FIG. 12, the first fastener (156) and the second fastener (157) may each engage the cable (130) such that the first rib and the second rib form a third hole (153) in which the cable (130) is disposed. The first fastener (156) and the second fastener (157) may each be pressed against the cable (130) from opposite directions to engage the cable (130), and then pressed toward the first hole (113) to engage the first hole (113), thereby closing the space between the cable (130) and the first hole (113) via the fastener (150).

The cover (170) may be opposite the base (111) and may cover the case (110). The cover (170) can protect the case. Alternatively, the case may be attached to a solar panel or the like without the cover (170). The cover (170) may be joined after the molding fluid has cured, or may be joined before the molding fluid has cured.

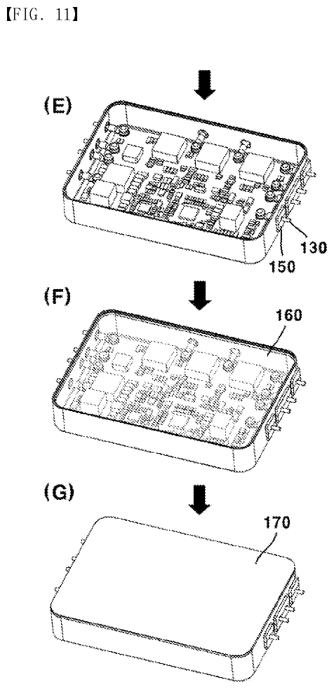

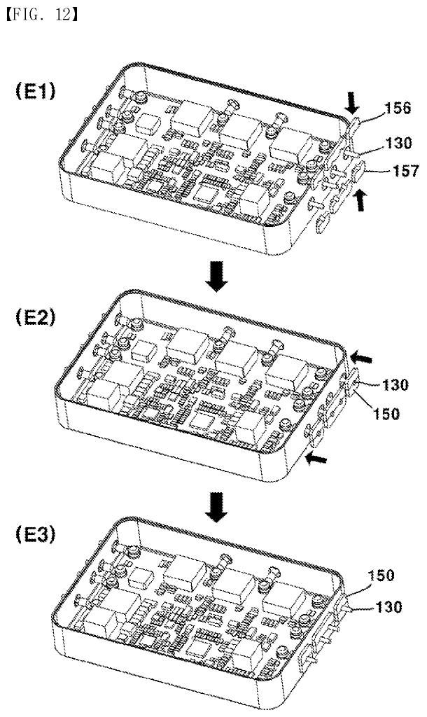

A power conversion device according to an embodiment of the present invention may be manufactured using the process of FIGS. 10 and 11. The power conversion device case may include a fixture (114) in a base (111) and a first hole (113) in a side plate (112), as shown in (A). A PCB with a substrate (120) may be placed on the base (111), the bottom case (B), but a second hole formed in the substrate (120) may be positioned in the fixture (114), i.e., the fixture (114) may guide engagement with the substrate (120).

The cable (130) can then be passed through the first hole (113) (C), and the fixture (114), the substrate (120), and the cable (130) can be joined via the connector (140). The cable (130) and the first hole (113) can then be engaged (E) via the fastener (150), and the case can be molded (F) by filling the interior with molding fluid (160). The fastener (150) can then be removed, and the cover (170) can be placed on top (G) to manufacture the power conversion device. The presence or absence of cover (170) may be optional. The fastener (150) may have an upper and lower two-part structure centered on the cable (130), as shown in FIG. 12, and may be assembled (E1) by first threading one side onto the cable, then the other, and then sliding it into the case (110) (E2) for assembly (E3). A molding holder (150), which is a fastener, may hold the cable (130) during molding to prevent it from bending.

As described above, by applying a molded structure to the manufactured power conversion device, reliability can be secured by preventing bending of the cable, and fire can be prevented. In addition, the cost can be reduced by eliminating the need for connectors to compensate for height, and the size can be reduced by eliminating the need for cable bending space.

The power conversion device case according to an exemplary embodiment of the present invention may comprise a base, a side plate, and a first hole. The following detailed description of the power inversion device case according to an exemplary embodiment of the invention corresponds to the detailed description of the power inversion device in FIGS. 1 to 12, with redundant descriptions omitted. The power conversion device case according to an exemplary embodiment of the present invention may comprise a base, a side plate extending perpendicularly from the base, and at least one first hole formed in the side plate of the case, the first hole being formed in a position corresponding to a position where a cable connecting to a substrate disposed inside the case is passed through and where the cable is connected to the substrate.

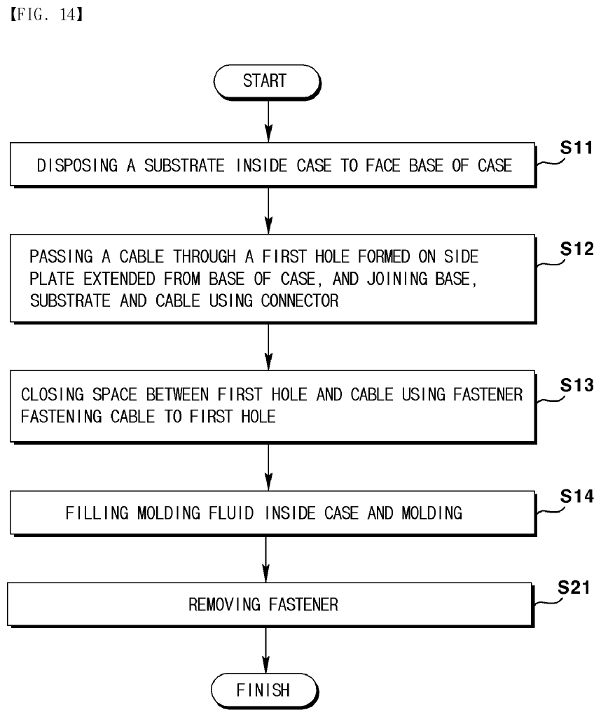

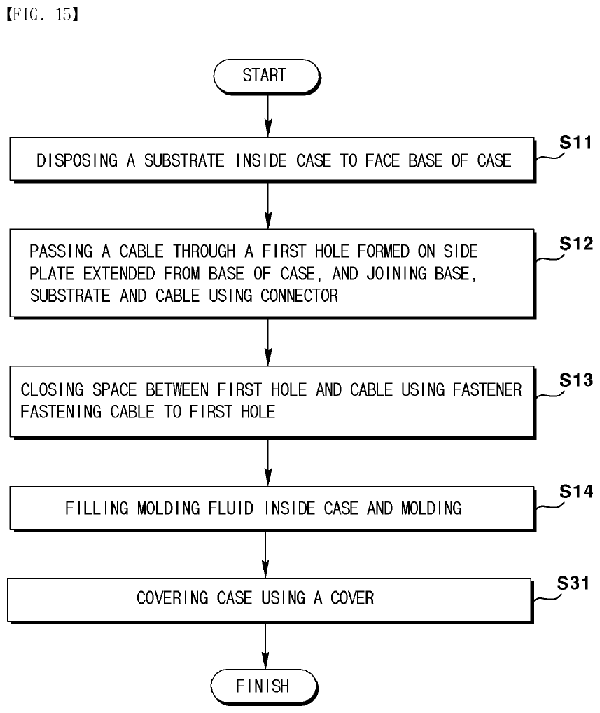

FIG. 13 is a flow chart of a power conversion device manufacturing method according to an exemplary embodiment of the present invention, and FIGS. 14 and 15 are flow charts of a power conversion device manufacturing method according to another exemplary embodiment of the present invention. The detailed description of each step in FIGS. 13 to 15 corresponds detailed description of the power conversion device in FIGS. 1 to 12, and redundant descriptions will be omitted hereinafter.

In step S11, a substrate is placed inside the case opposite to the base of the case, and in step S12, a cable is passed through a first hole formed in a side plate extending from the base of the case, and the base, the substrate, and the cable are joined by a connector. Then, in step S13, the space between the first hole and the cable is closed by means of a fastener for fastening the cable to the first hole, and in step S14, the interior of the case is filled with a molding liquid and molded.

In the step S13, a fastener may engage the first hole and the cable from the outer side of the case, and after the step S14, after the molding liquid has hardened, the fastener may be removed in step S21. Further, after the step S14, the case may be covered with a cover in step S31.

It should be understood that various modifications and variations will be apparent to one having ordinary skill in the technical field to which the invention belongs without departing from the essential features of the invention. Accordingly, the embodiments disclosed herein are intended to illustrate and not to limit the technical ideas of the invention, and the scope of the technical ideas of the invention is not limited by these embodiments. The scope of protection of the present invention shall be construed in accordance with the following claims, and all technical ideas within the scope of the equivalents shall be construed to be included in the scope of the present invention.

1.-10. (canceled)

11. A power conversion device, comprising:
a case comprising a base and a side plate extending in the vertical direction from the base;
a substrate disposed inside the case and facing the base; and
one or more first holes formed in the side plate of the case and through which a cable connected to the substrate passes,
wherein the first hole is formed at a position corresponding to a position where the cable is connected to the substrate.

12. The power conversion device of claim 11, wherein the first hole is formed at a location corresponding to a length from the base to a second surface of the substrate which is an opposite side of a first surface of the substrate facing the base.

13. The power conversion device of claim 11, wherein an interior of the case is filled with a molding fluid and molded.

14. The power conversion device of claim 11, comprising a connector connecting the cable to the substrate and disposed on a second surface of the substrate opposite a first surface of the substrate facing the base.

15. The power conversion device of claim 14, comprising a fixing part protruding from a surface of the base facing the substrate corresponding to a position of the connector,
wherein the substrate comprises a second hole corresponding to the fixing part, and
wherein the connector combines the fixing part, the substrate, and the cable.

16. The power conversion device of claim 11, comprising a cover facing the base and covering the case.

17. The power conversion device of claim 11, comprising a fastening part fastening the cable to the first hole.

18. The power conversion device of claim 17, wherein the fastening part comprises:
a first plate;
a stepped portion protruding from one surface of the first plate; and
a third hole penetrating the first plate and the stepped portion, with the cable located therein, and
wherein the third hole having a length from a center of the third hole to an outermost edge of the stepped portion corresponding to a radius of the first hole.

19. The power conversion device of claim 18, wherein a cross-sectional shape of the stepped portion is a ring shape in which a hole is formed, or a shape comprising a ring shape and a plurality of protrusions protruding from the ring shape.

20. The power conversion device of claim 17, wherein the fastening part comprises:
a first fastening part contacting with the cable in a first direction and comprising a semi-circularly shaped first rib on which the cable is located; and
a second fastening part contacting with the cable in a second direction opposite to the first direction and comprising a semi-circularly shaped second rib on which the cable is located.

21. The power conversion device of claim 20, wherein the first rib and the second rib form a third hole in which the cable is disposed.

22. The power conversion device of claim 11, wherein the cable comprises one or more input cables receiving power and one or more output cables outputting power.

23. The power conversion device of claim 11, wherein the substrate comprises power conversion elements receiving and converting multi-level power.

24. A power conversion device case, comprising:
a base;
a side plate extending in the vertical direction from the base; and
one or more first holes formed in the side plate,
wherein a cable connected to the substrate disposed inside the case passes the first hole, and
wherein the first hole is formed at a position corresponding to a position where the cable is connected to the substrate.

25. The power conversion device case of claim 24, comprising a fastening part fastening the cable to the first hole.

26. The power conversion device case of claim 25, wherein the fastening part comprises:
a first plate;
a stepped portion protruding from one surface of the first plate; and
a third hole penetrating the first plate and the stepped portion, with the cable located therein, and
wherein the third hole having a length from a center of the third hole to an outermost edge of the stepped portion corresponding to a radius of the first hole.

27. The power conversion device case of claim 25, wherein the fastening part comprises:
a first fastening part contacting with the cable in a first direction and comprising a semi-circularly shaped first rib on which the cable is located; and
a second fastening part contacting with the cable in a second direction opposite to the first direction and comprising a semi-circularly shaped second rib on which the cable is located.

28. A power conversion device manufacturing method, comprising:
disposing a substrate inside a case facing a base of the case;
passing a cable through a first hole formed in a side plate extending from the base of the case,
combining the base, the substrate, and the cable with a connector;
closing a space between the first hole and the cable with a fastening part fastening the cable to the first hole; and
molding an interior of the case with a molding fluid.

29. The power conversion device manufacturing method of claim 28, wherein the fastening part combines the first hole and the cable at an exterior side of the case, and comprising removing the fastening part after the step of molding.

30. The power conversion device manufacturing method of claim 28, comprising covering the case with a cover after the step of molding.
